(19) United States
(12) Patent Application Publication
(10) Pub. No.: US 2012/0148728 A1
(43) Pub. Date: Jun. 14, 2012

(54) METHODS AND APPARATUS FOR THE PRODUCTION OF HIGH PURITY SILICON

(75) Inventors: Manuel Vincente Vales Canle, Valencia (ES); Maria Tomas Martinez, Murcia (ES); Javier San-Segundo Sanchez, Alboraya (ES)

(73) Assignee: SILIKEN SA, Casas Ibanez (ES)

(21) Appl. No.: 12/964,331

(22) Filed: Dec. 9, 2010

(51) Int. Cl. C23C 16/24; C23C 16/442; C23C 16/52; C23C 16/455

(52) U.S. Cl. 427/58; 118/715; 118/712; 118/724; 118/722

(57) ABSTRACT

Methods and apparatus for the production of high purity silicon including a silicon deposition reactor with a gas distribution plate for injecting gas into the silicon deposition reactor.

### TECHNICAL FIELD

The present disclosure relates to methods and apparatus for producing high purity electronic grade silicon. More particularly, this disclosure relates to methods for producing high purity silicon by chemical vapor deposition (CVD) of a silicon-bearing gas on seed particles in a silicon deposition reactor.

### BRIEF DESCRIPTION OF THE DRAWINGS

FIG. 1 shows one embodiment of a silicon deposition reactor.

FIG. 2 shows a detailed view of one embodiment of a silicon deposition reactor.

FIG. 3 shows a detailed view of one embodiment of a gas injection zone of a silicon deposition reactor.

FIG. 4 shows a detailed view of one embodiment of a dehalogenation fluid-bed area of a silicon deposition reactor.

FIG. 5 shows a detailed view of one embodiment of a dehydrogenation fluid-bed area separated from a dehalogenation fluid-bed area with a flow control valve.

### DETAILED DESCRIPTION

The importance of improving energy production has led to an increasing interest in superior photovoltaic cells and solar panels. The development of more efficient solar panels has increased the demand for high-purity silicon for making the semiconductors used in the production of solar cells.

The production of high-purity polycrystalline silicon (polysilicon) may include the use of silanes or chlorosilanes as feedstock material to promote a chemical vapour deposition (CVD) reaction onto an existing high-purity silicon surface. Conventional methods use low-purity, metallurgical grade silicon as raw material for the synthesis of trichlorosilane (TCS). For the Siemens process, a common method of polycrystalline silicon production, silicon bearing-gas (normally silane, dichlorosilane or trichlorosilane), in combination with hydrogen, is mixed inside the reactor and then decomposed onto a filament of heated silicon. This method requires a high amount of energy per unit of mass of produced silicon (around 60 Kw-h/Kg of silicon to 90 Kw-h/Kg of polysilicon). During the Siemens process, the reactor is operated in a batch mode and the silicon is extracted from the reactor in form of rods. As such, an additional post treatment is needed to convert silicon rods into smaller chunks or beads suitable to be used in a conventional silicon ingot growing process.

A fluidized bed reactor technique for CVD of silicon may be a low cost alternative to the Siemens process. In a fluidized bed reactor processes, silicon is produced as polysilicon beads during a continuous CVD process using less energy than the production of the rods formed during the Siemens process. Fluidized bed reactors also promote improved contact between the reacting silicon-bearing gases and the surface of the silicon seeds, enhancing the thermal decomposition of the silicon bearing gases and promoting more efficient formation of elemental pure silicon on the surface of existing beads.

Despite the advantages of fluidized bed reactors, silicon deposition often occurs on the heated reactor walls and internal surfaces, including gas nozzles and distribution plates, that are in contact with silicon-bearing gases. The unwanted deposition and accumulation of silicon on the internal surfaces of the reactor limits the operability and efficiency of the fluidized bed reactor.

A silicon deposition reactor for the production of high-purity silicon is disclosed herein. In one such embodiment, the silicon deposition reactor may include a bed of granular solid materials, such as a bed of silicon particles that can be used as seed beads to seed a silicon decomposition reaction during which the seed silicon particles can increase in size because of the deposition of additional silicon on their surface. The seed beads with the added silicon product may be eventually removed from the reactor to recover the high purity silicon product. The seed beads may be “fluidized”, or suspended in the reactor, by injecting fluidizing gases into the reactor at sufficient velocities to agitate the beads. The fluidizing gases may be injected into the silicon deposition reactor through one or more inlet openings located around the reactor such as at the ends and at the sides of the reactor column.

In one embodiment of a silicon deposition reactor as disclosed herein, a silicon-bearing gas and/or a fluidizing gas may be injected into a reaction chamber from a gas injection zone comprising a gas distribution plate. The gas distribution plate may include one or more separate chambers configured to deliver the silicon-bearing gas and/or the fluidizing gas into the reaction chamber. In one particular embodiment, the distribution plate may be divided into at least two separate chambers designed to prevent any mixing of the silicon-bearing gas and the fluidizing gas before being injected into the reaction chamber. In one such embodiment, the at least two separate chambers comprise one or more gas outlets or orifices through which the silicon-bearing gas or the fluidizing gas are injected into the reaction chamber. In another such embodiment, the silicon-bearing gas and the fluidizing gas mix together after being injected out of the gas distribution plate and before reaching the reaction chamber.

In one embodiment, the silicon-bearing gas may be trichlorosilane (TCS) that can be injected into the reactor at the same location or a location adjacent to the injection of a fluidizing gas. When sufficiently heated, TCS decomposes in the reactor to form silicon on the seed silicon particles thereby increasing the diameter of the seed silicon particles over time and producing the desired high-purity silicon product. The following reaction may occur with TCS decomposition:

4SiHCl₃→Si+3SiCl₄+2H₂(thermal decomposition)

In another embodiment, a silicon-bearing gas may be injected in combination with hydrogen chloride, the weight ratio of hydrogen chloride diluted with the silicon-bearing gas not exceeding 2%. After the deposition of the silicon on the seed silicon particles, the resulting silicon product may then be recovered from the reactor and used for the production of semiconductors and photovoltaic cells.

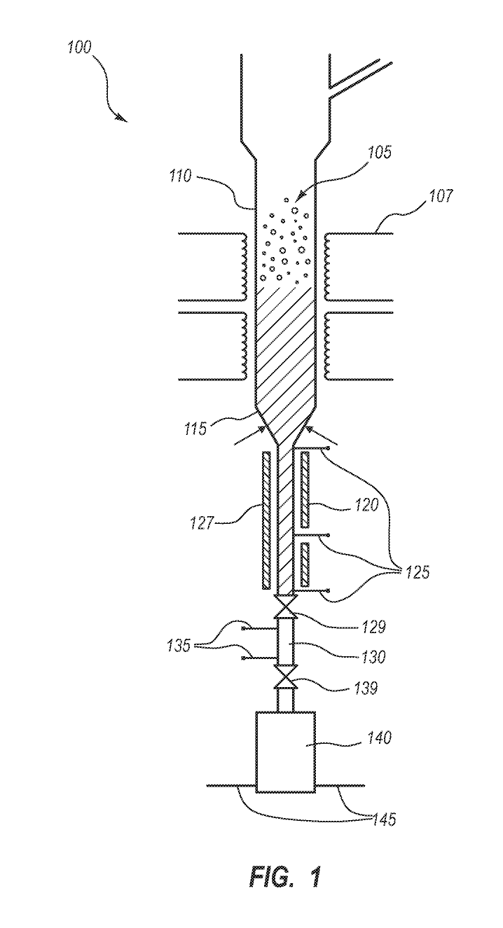

As shown in FIG. 1, one embodiment of a silicon deposition reactor for the production of high-purity silicon may be represented by the silicon deposition reactor 100 comprising a reaction chamber 110, a dehalogenation fluid-bed area 120, and a dehydrogenation fluid-bed area 130. In another embodiment, the silicon deposition reactor 100 may comprise a reaction chamber 110, a dehalogenation fluid-bed area 120, a dehydrogenation fluid-bed area 130, and a product recovery hopper 140. The deposition reactor 100 may include an elongate chamber or column configured to accommodate at least one bed of silicon particles 105, which may be used to seed a silicon decomposition process. The silicon particles 105 may be fluidized by injecting gases into one or more areas of the deposition reactor 100 in order to agitate or fluidize the silicon beads 105. In one such embodiment, the injected gasses may be injected into the reaction chamber 110 from one or more gas injection zones located, for example, at the bottom or sides of the reaction chamber 110. In another such embodiment, gasses may be introduced into the dehalogenation fluid-bed area 120, the dehydrogenation fluid-bed area 130, and the product recovery hopper 140. In a particular embodiment, the dehalogenation fluid-bed area 120 may include one or more gas injection zones 125. In another particular embodiment, the dehydrogenation fluid-bed area 130 may include one or more gas injection zones 135. In yet another embodiment, the product recovery hopper 140 may include one or more gas injection zones 145.

During the operation of a silicon deposition reactor 100 as described herein, one or more injected gasses may be delivered into the reaction chamber 110 through a gas injection zone comprising a gas distribution plate 115. The gas distribution plate 115 may be configured to deliver one or more of a silicon-bearing gas or a fluidizing gas into the reaction chamber 110. As used herein a “silicon-bearing gas” is a gas that includes silicon in the molecular formula of the gaseous species. A silicon-bearing gas may include gaseous species which thermally decompose to form polysilicon. Silicon-bearing gas which decomposes when heated may be selected from the group of monosilane, disilane, trisilane, trichlorosilane, dichlorosilane, monochlorosilane, tribromosilane, dibromosilane, monobromosilane, triiodosilane, diiodosilane and monoiodosilane. A silicon-bearing gas may also include those molecules that do not typically decompose to form polysilicon, such as silicon tetrachloride, silicon tetrabromide and silicon tetraiodide.

As used herein a “fluidizing gas” is a gas that is injected into a fluidized bed reactor to contribute to the fluidization of the silicon bead particles, but does not thermally decompose to form polysilicon. It should be understood that silicon-bearing gases may also contribute to the fluidization of the silicon bead particles in a fluidized bed reactor. Exemplary fluidizing gases may include hydrogen, helium, argon, silicon tetrachloride, silicon tetrabromide and silicon tetraiodide. In one embodiment, the concentration of the silicon-bearing gases injected into the reaction chamber 110 may range from approximately 20 mol % to 100 mol %.

In one embodiment, the average diameter of the silicon particles 105 may range from 500 microns to 4 mm. In another embodiment, the average diameter of the silicon particles 105 may range from 0.25 mm to 1.2 mm, or alternatively, 0.6 mm to 1.6 mm. In one embodiment, the silicon particles 105 may remain in the silicon deposition reactor 100 until a desired size is reached and the silicon product is removed from the reactor. In another embodiment, the time that the silicon particles 105 may remain in the silicon deposition reactor 100 may depend on the starting size of silicon particles 105. In one embodiment, the growth rate of the silicon particles 105 may depend, among other things, on the reaction conditions including gas concentrations, temperature and pressure. The minimum fluidization velocity (Umf) and design operational velocity may be determined by one of ordinary skill in the art based on various factors. The minimum fluidization velocity may be influenced by factors including gravitational acceleration, fluid density, fluid viscosity, particle density, particle shape, and particle size. The operational velocity may be influenced by factors including heat transfer and kinetic properties, such as height of the fluidized silicon particle bed, total surface area, flow rate of silicon precursor in the feed gas stream, pressure, gas and solids temperature, concentrations of species, and thermodynamic equilibrium point.

In one embodiment of a silicon deposition reactor 100 shown in FIG. 1, one or more control valves may be used to control the flow of silicon particles or gases in the silicon deposition reactor 100. In one such embodiment, the dehalogenation fluid-bed area 120 may be separated from the dehydrogenation fluid-bed area 130 with a control valve 129 that may be opened or closed to control the flow of silicon particles within the silicon deposition reactor 100. In another such embodiment, the dehydrogenation fluid-bed area 130 may be separated from the product recovery hopper 140 with a control valve 139 through which the high purity silicon product may be collected from the silicon deposition reactor 100.

The silicon deposition reactor 100 may be heated by one or more heating systems. In one embodiment, the reaction chamber 110, the dehalogenation fluid-bed area 120, and/or the dehydrogenation fluid-bed area 130 may have one or more heating systems. In one such embodiment, the reaction chamber 110 may be heated by at least one heating element 107 placed near or around the reaction chamber 110. In another such embodiment, the dehalogenation fluid-bed 120 area may heated by heat transfer elements 127. The heating system used with a silicon deposition reactor as described herein, such as silicon deposition reactor 100, may be a radiant, conductive, electromagnetic, infrared, microwave, or other type of heating system.

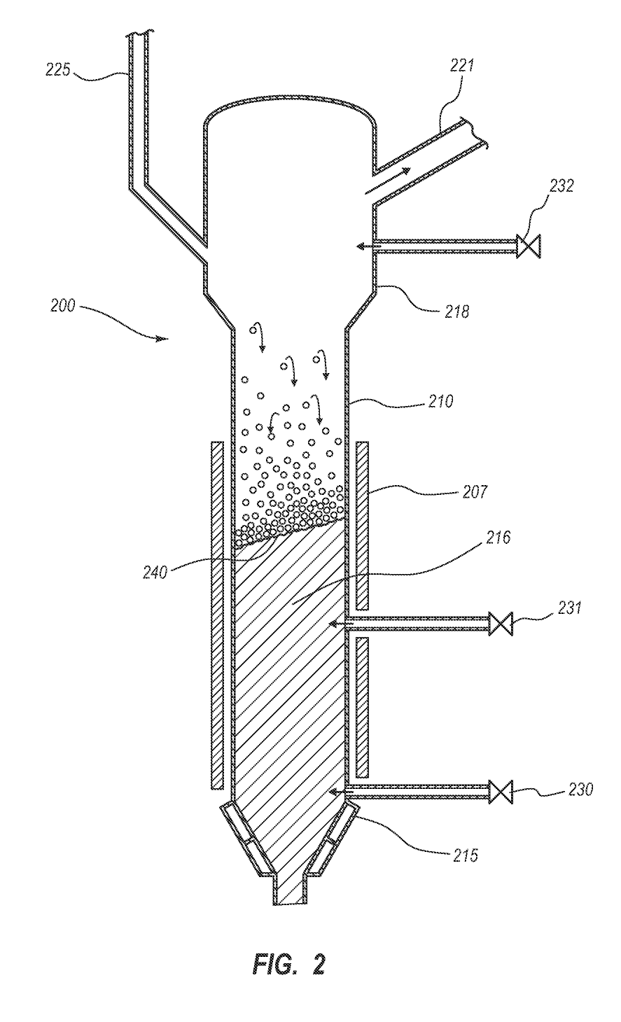

As shown in FIG. 2, the silicon deposition reactor 200 may include a reaction chamber 210 comprising a gas injection zone 215 and an expansion zone 218. The gas injection zone 215 may be located below the lower area of the reaction chamber 210 and designed to inject a silicon bearing gas and/or a fluidizing gas towards the reaction chamber 210 and the silicon particles located therein. In one embodiment, the expansion zone 218 may be located above the upper area of the reaction chamber 210 and comprise an area where the diameter of the silicon deposition reactor 200 increases and allows an expansion of the gasses therein. In another embodiment, the reaction chamber 210 may be in contact with, adjacent to, or surrounded by a heating system, such as heating elements 207, for controlling the reaction conditions within the reaction chamber 210. In certain embodiments, the expansion of the fluidizing gasses in the expansion zone 218 decreases the velocity of the fluidizing gasses, preventing the fluidized silicon particles from achieving entrainment velocity.

In one embodiment, the silicon deposition reactor 200 shown in FIG. 2 may comprise one or more inlet ports and one or more outlet ports for introducing or removing gasses and silicon particles from the reactor. In one such embodiment, the silicon deposition reactor 200 may comprise a silicon particle inlet 225 located in the expansion zone 218 and below the gas exit port 221. The reaction chamber 210 may be seeded with silicon particles introduced through the silicon particle inlet 225 during initial startup of the silicon deposition reactor 200 and as the silicon particles move through the reaction chamber 210 during the silicon deposition process. In another such embodiment, the silicon deposition reactor 200 may comprise one or more inlet ports such as inlet ports 230, 231, and 232. In one example, one or more inlet ports 230, 231, and 232 may be used for monitoring the pressure at desired positions within the silicon deposition reactor 200. In yet another such embodiment, the silicon deposition reactor 200 may comprise one or more gas outlets such as a gas outlet port 221 from which the fluidizing gasses and silicon bearing gasses may exit the reaction chamber 210.

In one embodiment of a silicon deposition reactor described herein, the process of silicon deposition may be controlled by maintaining an appropriate ratio between the total amount of reactive gases (flow in kilograms per hour) and the total surface area of the silicon particles available for silicon deposition. In another embodiment, particle agglomeration inside the reactor may be minimized by providing that the total flow of gases allow the fluidization of the particles inside the bed. In a particular embodiment of a silicon deposition reactor, the gas flow may be adjusted to be in a range in which the actual fluidization velocity (U) of the fluidization gases inside the reactor, compared to the minimum fluidization velocity (Umf) for a determined silicon particle size distribution inside the reactor, may be equal to or greater than a ratio (defined as U/Umf) ranging from approximately 2 to 7. In another particular embodiment, the ratio of U/Umf may be in a range from approximately 3 to 6, 3 to 5, 3 to 4, 4 to 7, 4 to 6, 4 to 5, 5 to 7, 5 to 6, 2 to 6, 2 to 5, 2 to 4, and 2 to 3. As used herein, the minimum fluidization velocity (Umf) defines the limit between a fluidized and a not fluidized bed. When the gas velocity U is in a condition in which 0<U<Umf, then particles may be quiescent, and the gases flow through the particle bed interstices. When actual gas velocity (U) reaches the minimum fluidization velocity value (Umf), the silicon particles inside the bed may be supported or fluidized by the gas flow. In one embodiment, at this minimum fluidization point of (U=Umf), the voidage of the bed may correspond to the loosest packing of a packed bed (not fluidized bed), and the pressure drop due to gas flow is the minimum necessary to support the total weight of the silicon particles inside the bed.

In one embodiment, the minimum fluidization velocity (Umf) may generally depends on gas properties (viscosity and density), and particle properties (particle size, shape, and density). In another embodiment, there can be a number of semi-empirical correlations used to determine the minimum fluidization velocity in a fluidized bed. In one such embodiment, the Wen&Yu correlation (1966) can be used to determine the minimum fluidisation velocity:

$${U}_{mf} = \frac{{μ}_{g}}{{d}_{{p}_{50 \%}} \cdot {ρ}_{g}} \cdot ( \sqrt{{C}_{1}^{2} + {C}_{2} \cdot Ar} - {C}_{1} )$$

Where, C1 and C2 are constants that can be empirically adjusted. In one particular embodiment, values for C1 may be between 28 and 34, and for C2 between 0.04 and 0.07. The variable Ar is the Archimedes number which is defined by the following expression:

$$Ar = \frac{{d}_{p , 50 \%} \cdot {ρ}_{g} \cdot ( {ρ}_{p} - {ρ}_{g} ) \cdot g}{{μ}_{g}^{2}}$$

For example, in one embodiment of a silicon deposition reactor having a diameter of 100 mm, filled with 30 Kg of silicon particles having an average particle diameter of 600 microns (standard deviation of 100 microns), the reactor at 800° C. and using trichlorosilane and hydrogen as silicon-bearing and fluidizing gasses respectively, the minimum fluidization velocity Umf can be estimated at around 0.09 m/s. The recommended fluidization velocity should be in a ratio between approximately 0.2 m/s and 0.7 m/s. In another particular embodiment, the ratio of the flow of reactive gases to the total surface area of the silicon particles may be in a range from approximately 3 to 6, 3 to 5, 3 to 4, 4 to 7, 4 to 6, 4 to 5, 5 to 7, 5 to 6, 2 to 6, 2 to 5, 2 to 4, and 2 to 3. The total surface area of the silicon particles inside the silicon deposition reactor may be estimated from the particle size distribution and from the bed height. In certain embodiments of a silicon deposition reactor disclosed herein, the silicon particle size and bed height inside the reactor may be monitored to control and regulate the deposition reaction. The particle size distribution may be evaluated by sampling the silicon particles directly, such as sampling the silicon particles from the recovery hopper.

As shown in FIG. 2, certain embodiments of the silicon deposition reactor as disclosed herein may comprise two or more gas inlets positioned below the freeboard zone 240 of the reaction chamber 210, such as, for example, inlet ports 230 and 231. In another embodiment of a silicon deposition reactor, such as silicon deposition reactor 200, one or more inlet ports, like inlet port 232, may be located above the freeboard zone 240. In yet another embodiment, a minimum gas flow (flushing flow) may be injected into the silicon deposition reactor 200 through one or more of the gas inlets in order to avoid gas inlet plugging by silicon particles or silicon deposition. The gas inlets, such as inlet ports 230, 231, and 232 may comprise pressure monitors and be used to measure gas pressure differentials for purposes of adjusting and controlling the reactor conditions such as bed agitation and bed height. In a particular embodiment, an inert gas may be introduced as a flushing gas through the inlet ports comprising between 2% and 10% of the minimum total gas flow to prevent unwanted silicon deposition. An “inert gas” is one of (or a mixture of) noble gases, such as argon, or non-reactive gases such as nitrogen.

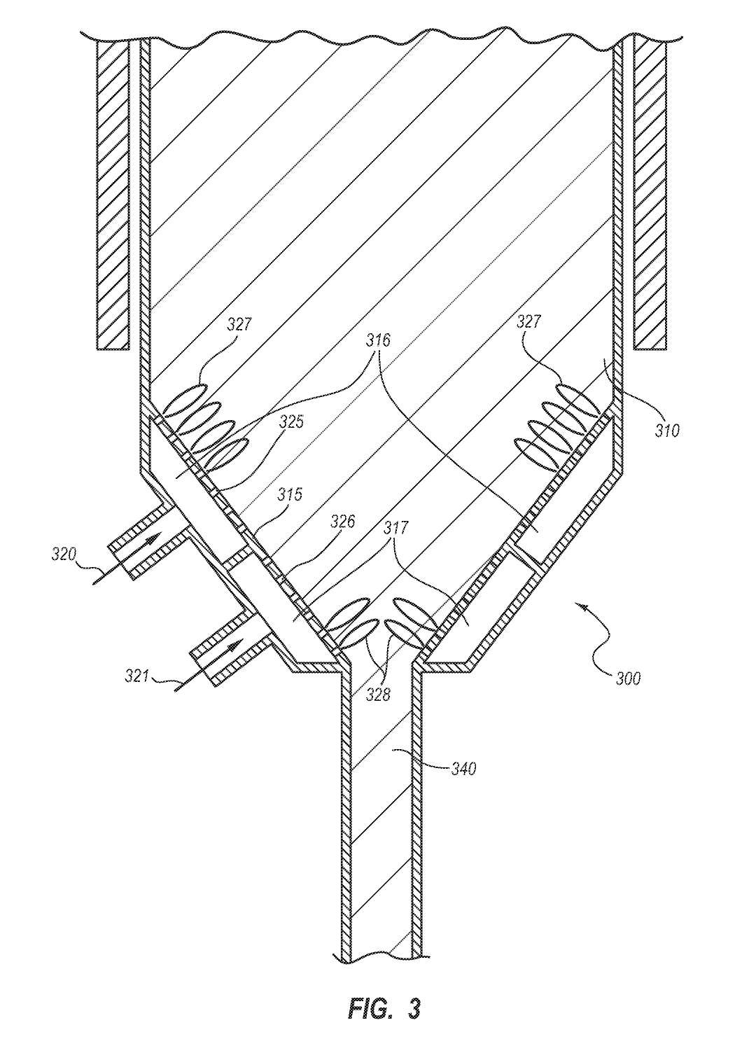

As shown by FIG. 3, one embodiment of a silicon deposition reactor may comprise at least one gas injection zone for providing gas supply to the reaction chamber 310. In one such embodiment, the gas injection zone may include a gas distribution plate 315 designed to deliver one or more of a silicon-bearing gas or a fluidizing gas into the reaction chamber 310. In another such embodiment, the gas distribution plate 315 may be internally divided into one or more injection chambers. In a particular embodiment, the gas distribution plate 315 may include an upper injection chamber 316 and a lower injection chamber 317.

In one embodiment, the upper injection chamber 316 may be provided with a silicon-bearing gas through one or more inlet ports, such as inlet port 320. The silicon-bearing gas in the upper injection chamber 316 may be injected into the reaction chamber 310 through one or more orifices 325. In another embodiment, the lower injection chamber 317 can be provided with a fluidizing gas through one or more inlet ports, such as inlet port 321. The fluidizing gas in the lower injection chamber 317 can be injected into the reaction chamber 310 through one or more orifices 326. In a particular embodiment, the upper injection chamber 316 and the lower injection chamber 317 may be provided with mixtures of one or more fluidizing and/or silicon-bearing gases. In certain embodiments of the silicon deposition reactor as described herein, the shape and disposition of the gas distribution plate 315 and the orifices thereof may allow the one or more silicon-bearing gases and fluidizing gases to be injected inside the reaction chamber 310 before the gases reach the heated area or surfaces of the reaction chamber 310.

The silicon deposition reactor as disclosed herein can include a gas distribution plate 315 with a relative position and inclination angle that may allow the injected jets of gas 327 to avoid directly impacting the heated surfaces or walls of the reaction chamber 310, thereby avoiding undesired silicon deposition near the gas injection area. In one embodiment, the gas distribution plate 315 is designed to produce jets of gas 327 allowing the fluidizing gasses to be injected in a bubbling phase before mixing with the silicon-bearing gas. In certain embodiments, the bubbling phase is characteristic of an injected jet of gas wherein bubbles of gas form after the gas in injected into a fluidized particle bed. In another embodiment, the orifice 325 diameter may be designed to inject a steady flow of gas and allow a gas pressure drop as measured between the inlet port 320 and the bottom of the fluidized particle bed that may be, for purposes of example only, approximately equal to or similar to the pressure drop as measured from the bottom of the fluidized particle bed to the top of the fluidized particle bed. For example, the gas distribution plate 315 may comprise an orifice 325 diameter that provides for a gas pressure drop as measured between the inlet port 320 and, with reference to FIG. 2, the inlet port 230 that may be approximately equal to or in the same range of the pressure drop in the fluidized particle bed, measured as the differential pressure between inlet ports 230 and 232. In particular embodiments, the ratio between pressure drop in the gas distribution plate 315 and the pressure drop in the fluidized particle bed is known as the ΔP ratio and may be kept between approximately 0.5 and 2.5, between 0.7 and 1.5, and alternately between 0.9 and 1.1. In certain embodiment, pressures measured inside the silicon deposition reactor 300 may range from approximately 0.1 bar to 1.0 bar. In one such certain embodiment, pressures measured inside the silicon deposition reactor 300 may be approximately 0.1 bar, 0.2 bar, 0.3 bar, 0.4 bar, 0.5 bar, 0.6 bar, 0.7 bar, 0.8 bar, 0.9 bar, 1.0 bar, or more.

In one embodiment of a silicon deposition reactor as disclosed herein, the fluidizing gasses injected into the reaction chamber may be used as purging gases that control the concentration of the gases. In one such embodiment, the fluidizing gases may be used to control the concentration of silicon-containing gases within the silicon particle bed. With reference to FIG. 3, in one embodiment of the silicon deposition reactor 300, halosilanes may injected from the gas distribution plate 315 and used to fluidize the silicon particle bed. In another embodiment, the gases used to fluidize the silicon particles may be free from halosilanes. In one such embodiment, when halosilanes are not used in the fluidizing gases, the upward flow of fluidizing gases 328 exiting from the orifices 326 of the gas distribution plate 315 and above the dehalogenation fluid-bed area 340, may act not only as fluidizing gases but also as purging gases, allowing silicon particles in this area to be free from the halosilanes or to minimize the content of halosilanes, avoiding the formation of silicon agglomerates near the dehalogenation fluid-bed area 340.

The gases and silicon particles used within a silicon deposition reactor as disclosed herein may be heated during the production of high purity silicon to temperatures ranging from approximately 500° C. to approximately 1200° C. For example, certain areas of the silicon deposition reactor 100 shown in FIG. 1 may be heated by the heating element 107 such that the silicon particles 105 and the silicon-bearing gases and the fluidizing gases within the reaction chamber 110 are heated to a temperature ranging from approximately 600° C. to 1100° C., or from 700° C. to 1000° C., or from 700° C. to 900° C., or from 750° C. to 850° C., or from 800° C. to 1000° C. In one embodiment, the temperatures in the reaction chamber 110 may be maintained at approximately between 750° C. and 1050° C., 850° C. and 1000° C., and 900° C. to 950° C. In particular embodiments, the gas flow calculations through the gas distribution plate 115 may be performed to provide a fluidization ratio in the reaction chamber 110 ranging between approximately 3×Umf to 9×Umf, 4×Umf to 8×Umf, and 5×Umf to 7×Umf to keep a proper degree of agitation of the silicon particles 105, and also ease the heat transfer between reactor walls and silicon particles. In another embodiment, the temperature difference between the walls of the reactor chamber 110 and the silicon particles 105 may not exceed 50° C. to avoid unwanted silicon deposition on the reactor walls.

In one embodiment of a silicon deposition reactor, the temperature of the silicon-bearing gases can be below its decomposition temperature in certain areas of the reactor to avoid undesired silicon deposition. In one particular embodiment, the temperature of the silicon-bearing gas may be at from approximately 250° C. to 350° C. as the gas passes through the gas distribution plate 315 and into the reaction chamber 310 (FIG. 3) in order to avoid the deposition of unwanted silicon on the surfaces and in the orifices 326 and 327 of the gas distribution plate 315. For example, the silicon-bearing gas may be at a temperature below approximately 250° C., 260° C., 270° C., 275° C., 280° C., 290° C., 300° C., 310° C., 320° C., 330° C., 340° C., and 350° C. in order to avoid the deposition of unwanted silicon.

In another embodiment, unwanted silicon deposition on the surface of the distribution plate 315 may be avoided by providing a minimum distance between the position of the gas distribution plate 315 and the heating system. In one such embodiment, the gas distribution plate 315 is separated by approximately from 50 mm to 80 mm away from a heating system or heating element used for heating the reaction chamber 310. In another such embodiment, the gas distribution plate 315 is separated by at least approximately from 50 mm, 55 mm, 65 mm, 70 mm, 75 mm, and 80 mm away from a heating system or heating element used for heating the reaction chamber 310. The separation between the gas distribution plate 315 and the heating system or heating element allows the gases inside and at the surface of the gas distribution plate 315 to have a temperature that is below the silicon decomposition temperature before being injected out into the higher temperatures found in heated zone of the reaction chamber 310.

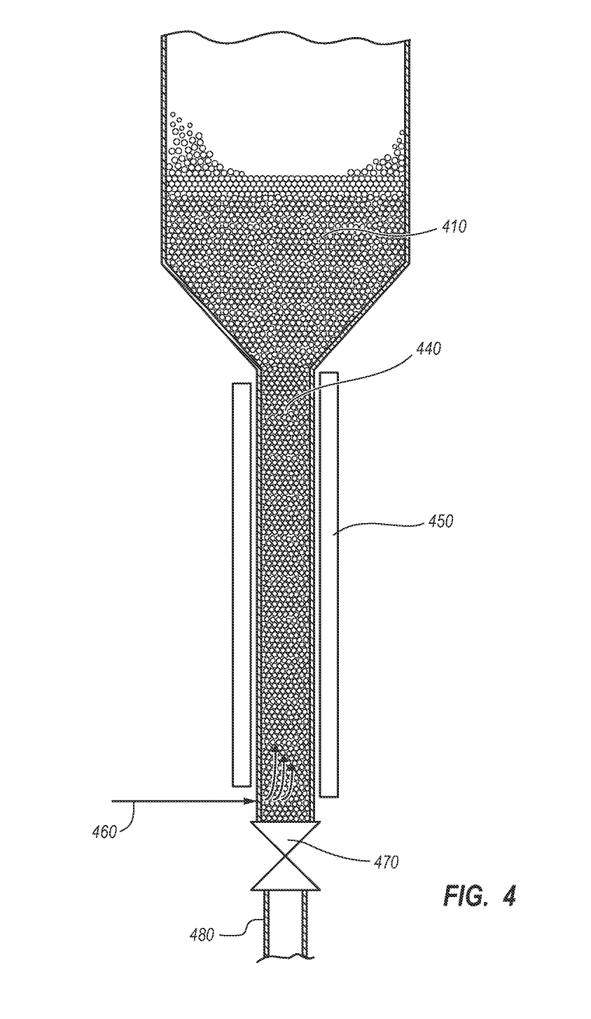

A silicon deposition reactor as disclosed herein may include a dehalogenation fluid-bed area 440 as shown in FIG. 4. In one embodiment, the dehalogenation fluid-bed area 440 may comprise a central chamber that is in direct communication with the bottom portion of the reaction chamber 410 as it nears the gas distribution plate. In another embodiment, the dehalogenation fluid-bed area 440 includes a jacketed tube 450 and at least one gas inlet port 460. The gas inlet port 460 may provide a non-silicon bearing gas, such as a fluidizing gas which does not include halosilanes. The dehalogenation fluid-bed area 440 may comprise a flow control valve 470 that can control the flow of silicon particles and gas moving between the reaction chamber 410 and the dehalogenation fluid-bed area 440.

In one embodiment, when the flow control valve 470 is closed, silicon particles inside the dehalogenation fluid-bed area 440 remain fluidized by the gas entering by the gas inlet port 460. The degree of fluidization for the dehalogenation fluid-bed area 440 may allow the displacement and purging of silicon-bearing gasses, such as halosilanes, from the bed of silicon particles. The size of the dehalogenation fluid-bed area 440 may be chosen in such a way that the diameter ratio, described as the ratio between the inner diameter of the reaction chamber 410, measured at the heating area, and the inner diameter of the dehalogenation fluid-bed area 440, is between approximately 2 and 8, alternatively between 3 and 7, and optionally between 5 and 6.

In one embodiment, of a silicon deposition reactor as disclosed herein, the fluidization ratio of the silicon particles within the dehalogenation fluid-bed area may be controlled to improve the efficiency of the silicon deposition process. As used herein, the fluidization ratio is defined as the relationship between the actual fluidization velocity and the minimum fluidization velocity. If the actual fluidization velocity exceeds the minimum fluidization velocity value, the dehalogenation fluid-bed area 440 may move from a bubbling fluidization condition to a slugging fluidization condition. Slugging fluidization can cause the silicon particles in the dehalogenation fluid-bed area 440 to be displaced upwards out of the dehalogenation fluid-bed area 440 and back into the reaction chamber 410, where they are again exposed to a silicon-bearing gas environment. Slugging fluidization may be undesirable because it can limit the efficiency of the dehalogenation fluid-bed area 440 and the silicon deposition process. In certain embodiments, the fluidization ratio inside the dehalogenation fluid-bed area 440 is maintained in a range between approximately 0.6 and 1.4, 0.8 and 1.2, or 0.9 and 1.1. For example, in a dehalogenation fluid-bed area having a diameter of 30 mm, totally filled with silicon particles having an average diameter of 600 microns (standard deviation of 100 microns), and at 200° C., the minimum fluidization velocity Umf can be estimated at around 0.15 m/s. Accordingly, the fluidization velocity may be in a range between approximately 0.1 m/s and 0.2 m/s.

In another embodiment of a silicon deposition reactor as disclosed herein, the condensation of gaseous halosilanes in the dehalogenation fluid-bed area 440 may be prevented by maintaining the temperature of the walls of the dehalogenation fluid-bed area 440 above the condensation temperature limits of halosilanes. In one such embodiment, the dehalogenation fluid-bed area 440 may be maintained at a temperature between approximately 90° C. and 300° C. in order to avoid condensation of gaseous halosilanes. In another such embodiment, the dehalogenation fluid-bed area 440 can be surrounded with a jacked tube 450 comprising a thermal fluid, which may be heated to a temperature between approximately 90° C. and 300° C., alternatively between 120° C. and 250° C., and optionally between 150° C. and 200° C.

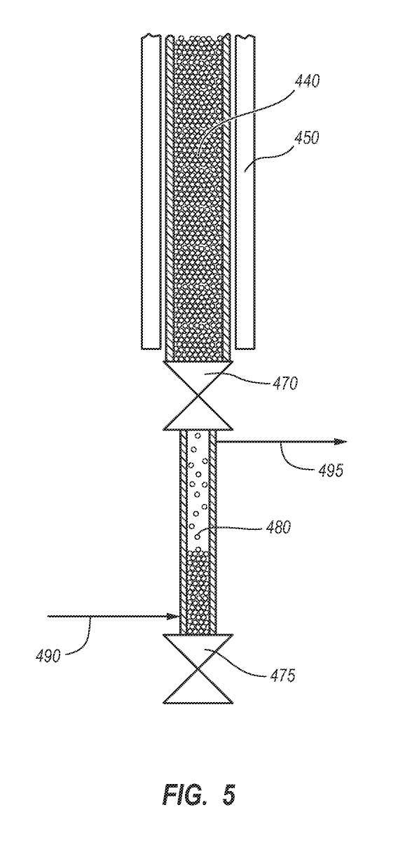

A silicon deposition reactor as shown in FIG. 5, may include a dehalogenation fluid-bed area 440 equipped with a solids flow control valve 470 configured to control the flow of solids moving from the dehalogenation fluid-bed area 440 to the dehydrogenation fluid-bed area 480. In one embodiment, when the flow control valve 470 is open, the bed of silicon particles in the dehalogenation fluid-bed area may transfer to the dehydrogenation fluid-bed area 480. As the dehalogenation fluid-bed area 440 is emptied through the control valve 470, silicon particles may move from the reaction chamber 410 (FIG. 4) into the dehalogenation fluid-bed area 440. In another embodiment, the dehydrogenation fluid-bed area 480 is separated from the dehalogenation fluid-bed area by the solids flow control valve 470 and also separated from the product recovery hopper by a second isolation valve 475. Silicon particles inside the dehydrogenation fluid-bed area 480 can be fluidized by an inlet port 490 that may introduce an inert gas, such as argon or nitrogen, that displaces hydrogen through the exit port 495.

With reference to FIG. 4, there may be certain conditions that control the movement of silicon particles through the control valve 470, including the residence time of the silicon particles in the reaction chamber 410 and the dehalogenation fluid-bed area 440. In one embodiment, the residence time of the silicon particles inside the dehalogenation fluid-bed area 440, measured as the time it takes for a silicon particle to move from the bottom of the reaction chamber 410 through to the bottom of the dehydrogenation fluid-bed area 440, may be approximately the same as the time needed for a purging of halosilanes from the halogenation fluid-bed area 440 until reaching a target value of a desired ppm (parts per million). For example, the residence time of the silicon particles inside the dehalogenation fluid-bed area 440 may be approximately less than 6 hours, less than 4 hours, and less than 3 hours.

In another embodiment of a silicon deposition reactor, the solids flow control valve 470 may control the residence time of silicon particles within the reaction chamber 410, measured as the time between when a seed silicon particle is introduced into the reaction chamber 410 and when this seed silicon particle exits the bottom of the reaction chamber 410. In one such embodiment, the residence time of the silicon particles inside the dehalogenation fluid-bed area 440 may determine the final size of the silicon particle and consequently, the amount of silicon deposited on its surface. In another such embodiment, the flow (measured in Kg/h) of fluidizing and reacting gases and the opening and closing times of the solids flow control valve 470 may determine the mean value of silicon particle size.

### EXAMPLES

The specific examples included herein are for illustrative purposes only and are not to be considered as limiting to this disclosure. The compositions referred to and used in the following examples are either commercially available or can be prepared according to standard literature procedures by those skilled in the art.

### Example 1

### Measuring Deposition Rates from Trichlorosilane as Reacting Gas onto Silicon Seeds and Controlling Process Parameters in a Prototype System

A prototype silicon deposition reactor system was assembled with a reaction chamber (80 mm inner diameter, 2.5 m height), a dehalogenation fluid-bed system (20 mm inner diameter, 1.5 m height), and a dehydrogenation fluid-bed system (15 mm diameter, 35 cm height). The reaction chamber was equipped at the top with an expansion zone (150 mm diameter, 0.5 m height). Pressure at the gas exit port was fixed to 1000 mbar (relative). The reactor was heated by an external heating system up to a temperature of 900° C. The bottom part of the reaction chamber consists of a conical, orifice type gas distribution plate divided in two different, separated chambers. The system was initially filled with silicon seed particles having an average diameter of 500 microns, including the complete filling of the dehalogenation fluid-bed area and the reaction chamber to a bed height of 1 m, as measured from the top of the conical gas distribution plate. Through the upper chamber of the gas distribution plate, a gas of 100% trichlorosilane (SiHCl₃), preheated up to 300° C., was injected. Through the lower chamber of the gas distribution plate, a flow of 100% hydrogen gas (H₂), preheated up to 300° C., was injected. The molar ratio between hydrogen and trichlorosilane was 4:1. The fluidization ratio inside this reactor was kept at a constant value of 5×Umf for the duration of the test.

The dehalogenation fluid-bed area was jacketed by a thermal fluid, allowing a wall temperature of 150° C., and was separated from the dehydrogenation fluid-bed area by a solids control valve, which was normally closed. A planar, O-ring shaped gas distribution plate was located in the bottom of the dehydrogenation fluid-bed area. This gas distribution plate consisted of a ring with a central opening of 10 mm that allows passage through to the flow control valve, and was equipped with 10 orifices, 0.3 mm diameter each, radially and uniformly distributed around the ring. Through the orifices of the gas distribution plate, a gaseous mixture of hydrogen and nitrogen was injected to keep a fluidization ratio of 0.9×Umf.

The flow control valve was initially closed, allowing the total filling of the dehydrogenation fluid-bed area. After filling, the open-close cycles for the solids flow control valve was set up, allowing an opening of the valve every 50 minutes. After closing of this valve, additional silicon seeds were fed to the reaction chamber until a constant silicon particle bed height was reached.

After finalizing the reaction conditions, the silicon deposition reaction was carried out and silicon particles were grown from an average of 500 microns to an average of 598-635 microns. The fluidization conditions (5×Umf) and reactor diameter allowed a slugging condition in the reactor and a high degree of agitation, so no particle segregation by size was observed. High bed agitation also allowed a good heat transfer between reactor walls and the silicon particles ensuring that the temperature gradient between reactor walls and the bed of particles did not exceed 25° C. In addition, the temperature in the bottom area of the reaction chamber (near the distribution plate) was close to a mean temperature value of 670° C. After the test, it was observed that the surface of the distribution plate in contact with silicon particles was free of unwanted silicon deposits near the gas injecting orifices. Once the targeted average silicon particle size was reached, this size was kept constant by the regulation of the opening and closing times of the solids flow control valve, and bed height was kept constant by the addition of new silicon seed particles through the silicon seed feeding tube. The remaining gaseous traces of chlorosilanes were removed by the hydrogen flow entering the reactor through the gas distribution plate in the dehalogenation fluid-bed area.

### Example 2

### Measuring Deposition Rates from Trichlorosilane as Reacting Gas onto Silicon Seeds and Controlling Process Parameters in a Scaled System

A prototype silicon deposition reactor system with a reaction chamber (150 mm inner diameter, 4 m height), a dehalogenation fluid-bed system (25 mm inner diameter, 1.5 m height), and a dehydrogenation fluid-bed system (15 mm diameter, 50 cm height) was assembled. The dehalogenation fluid-bed area and the dehydrogenation fluid-bed area were separated by a disk flow control valve, which was normally closed.

The reaction chamber was equipped at the top with an expansion tube (250 mm diameter, 2 m height). Pressure at the gas exit port was maintained at 1500 mbar (relative). The reactor was heated by an external heating system to a temperature of 950° C. The bottom part of the reactor consists of a conical, orifice type gas distribution plate divided into two different, separated chambers. The system was initially filled with silicon seeds, having an average diameter of 500 microns, resulting in the complete filling of the dehalogenation fluid-bed area and the reaction chamber with a final bed height of 2 m in the reaction chamber, as measured from the top of the conical gas distribution plate. Through the upper chamber of the gas distribution plate, a gas with 100% trichlorosilane (SiHCl₃), preheated up to 300° C. was injected into the reaction chamber. Through the lower chamber of the gas distribution plate, a flow of 100% hydrogen gas (H₂), preheated up to 300° C. was injected. The molar ratio between hydrogen and trichlorosilane was 3.5:1. The fluidization ratio inside this reactor was kept at a constant value of 5×Umf throughout the test

The dehalogenation fluid-bed area was jacketed by a thermal fluid, allowing a wall temperature of 250° C. The dehalogenation fluid-bed area was separated from the dehydrogenation fluid-bed area by a disk flow control valve, which was normally closed. A planar, O-ring shaped gas distribution plate was located in the bottom of the dehydrogenation fluid-bed area. The gas distribution plate consisted of a ring with a central orifice of 10 mm, allowing passage to the solids flow control valve, and it was equipped with 15 orifices, 0.3 mm diameter each, radially and uniformly distributed around the ring. Through the orifices, a gaseous mixture of hydrogen and nitrogen was injected to keep a fluidization ratio of 0.9×Umf.

The solids flow control valve was initially closed, allowing the total filling of the dehydrogenation fluid-bed area. After filling, the open-close cycles for the solids flow control valve was set up, allowing an opening of the valve every 50 minutes. After closing of this valve, additional silicon seeds were fed to the reaction chamber until a constant silicon particle bed height was reached.

The deposition reaction was carried out and the silicon particles were grown from an average of 500 microns to an average of 750-900 microns. The fluidization conditions (5×Umf) and reactor diameter allowed a slugging condition in the reactor and a high degree of agitation, so no particle segregation by size was observed. As it occurred with reactor mentioned in example 1, a good heat transfer between reactor walls and the particles was also observed, so the temperature gradient between reactor walls and the bed of particles did not exceed in this case 40° C. In addition, the temperature in the bottom area of the reactor (near the gas distribution plate) was close to a mean temperature value of 630° C. After the test, no deposits or plugged orifices were observed in the distribution plate. Bed height and particle size was controlled by adjusting the relationship between the opening of the flow control valve and the addition of new silicon seed particles.

1. A silicon deposition reactor for making high purity silicon, the silicon deposition reactor comprising:
a gas injection zone comprising a gas distribution plate for injecting gas into the silicon deposition reactor, wherein the gas distribution plate is divided into a first chamber and a second chamber and wherein a gas in the first chamber will not mix with a gas in the second chamber before being injected into the silicon deposition reactor.

2. The silicon deposition reactor of claim 1, wherein the first chamber of the gas distribution plate comprises at least one orifice configured to allow a gas to pass from the first chamber into the silicon deposition reactor, and wherein a jet of gas exiting from the at least one orifice of the first chamber does not directly contact an internal surface of the silicon deposition reactor; and
wherein the second chamber of the gas distribution plate comprises at least one orifice configured to allow a gas to pass from the second chamber into the silicon deposition reactor and wherein a jet of gas exiting from the at least one orifice of the second chamber does not directly contact an internal surface of the silicon deposition reactor.

3. The silicon deposition reactor of claim 2, wherein the first chamber of the gas distribution plate is configured to deliver at least one of a silicon-bearing gas, a fluidizing gas or a mixture thereof, and wherein the second chamber of the gas distribution plate is configured to deliver at least one of a silicon-bearing gas, a fluidizing gas or a mixture thereof.

4. The silicon deposition reactor of claim 3, wherein the first chamber comprises a fluidizing gas and the second chamber contains a silicon-bearing gas, and wherein the at least one orifice of the first chamber is configured so that the jets of the fluidizing gasses are injected in a bubbling phase before mixing with the silicon-bearing gas injected from the second chamber.

5. The silicon deposition reactor of claim 1, further comprising:
a reaction chamber in fluid communication with the gas injection zone, wherein the reaction chamber is heated by at least one heating system, and the gas injection zone is at a temperature less than the reaction chamber.

6. The silicon deposition reactor of claim 5, wherein the first chamber of the gas distribution plate is configured to deliver a fluidizing gas and the second chamber of the gas distribution plate is configured to deliver a silicon-bearing gas and wherein the silicon-bearing gas and the fluidizing gas are configured to mix together before entering the reaction chamber.

7. The silicon deposition reactor of claim 1, wherein the gas distribution plate is at a temperature below the thermal decomposition temperature of a silicon-bearing gas that causes silicon deposition.

8. The silicon deposition reactor of claim 5, further comprising an expansion zone positioned above the reaction chamber, wherein the expansion zone has a diameter greater than the reaction chamber.

9. The silicon deposition reactor of claim 8, further comprising a pressure measurement system, the pressure measurement system comprising:
at least one inlet port located above the gas distribution plate;
at least one inlet port located at the reaction chamber below the position of a freeboard of a silicon particle bed within the reaction chamber;
at least one inlet port located at the expansion zone; and
at least one pressure gauge located at each of the inlet ports for measuring the pressure difference between the inlet ports.

10. The silicon deposition reactor of claim 9, wherein an inert gas is introduced at least one inlet port and comprising between 2% and 10% of the total gas flow.

11. The silicon deposition reactor of claim 3, where the silicon-bearing gas configured to be delivered through the first chamber or the second chamber of the gas distribution plate is selected from: silane, disilane, trisilane, dichlorosilane, trichlorosilane, dibromosilane, tribromosilane, diodosilane, tribromosilane, silicon tetrachloride, silicon tetrabromide or mixtures thereof.

12. The silicon deposition reactor of claim 3, wherein an internal wall of at least one of the first chamber and the second chamber of the gas distribution plate is maintained at a temperature ranging from approximately between 50° C. and 100° C. below the thermal decomposition temperature of the silicon-bearing gas configured to be delivered through the first chamber or the second chamber of the gas distribution plate.

13. The silicon deposition reactor of claim 3, where the silicon-bearing gas configured to be delivered through the first chamber or the second chamber of the gas distribution plate is injected in combination with hydrogen chloride, the molar ratio of hydrogen chloride diluted with the silicon-bearing gas not exceeding 2%.

14. The silicon deposition reactor of claim 3, where the fluidizing gas used in the first chamber or the second chamber is selected from: hydrogen, nitrogen, helium, argon, silicon tetrachloride, silicon tetrabromide, silicon tetraiodide, or mixtures thereof.

15. The silicon deposition reactor of claim 1, where the gas distribution plate is cooled by means of a thermal fluid.

16. The silicon deposition reactor of claim 3, where the gas configured to be delivered through one of the first chamber or the second chamber of the gas distribution plate is a fluidizing gas that excludes any silicon-bearing gas, and the fluidizing gas is preheated and configured to be introduced into the first chamber or the second chamber at a temperature between 550° C. and 650° C.

17. The silicon deposition reactor of claim 5, wherein the reaction chamber is heated to a temperature of between approximately 500° C. to approximately 1200° C.

18. The silicon deposition reactor of claim 17, wherein the reaction chamber is heated to a temperature ranging from approximately 700° C. to approximately 900° C.

19. The silicon deposition reactor of claim 1, further comprising:
a reaction chamber located above the gas injection zone;
a dehalogenation fluid-bed area located below the gas injection zone and in fluid communication with the reaction chamber, the dehalogenation fluid-bed area comprising:
a central chamber configured to hold silicon particles, the diameter of the central chamber being smaller than the diameter of the reaction chamber; and
at least one inlet port configured for introducing a fluidizing gas into the central chamber.

20. The silicon deposition reaction of claim 19, wherein the fluidizing gas is selected from hydrogen, helium, argon and/or mixtures thereof, excluding any silicon-bearing gas.

21. The silicon deposition reaction of claim 19, wherein the flow of the fluidizing gas is sufficient to keep a fluidization state of the silicon particles inside the dehalogenation fluid-bed area in the range of from approximately 0.7×Umf to 1.3×Umf.

22. The silicon deposition reaction of claim 19, wherein the dehalogenation fluid-bed area is maintained at a temperature between approximately 90° C. and 300° C.

23. The silicon deposition reactor of claim 19, wherein the dehalogenation fluid-bed area further comprises a flow control valve.

24. The silicon reaction of claim 23, wherein the solids flow control valve is configured to be open or closed depending on at least one pressure measured within the reaction chamber.

25. The silicon deposition reactor of claim 19, further comprising:
a dehydrogenation fluid-bed area located below the dehalogenation fluid-bed area and in fluid communication with the dehalogenation fluid-bed area, the dehydrogenation fluid-bed area comprising:
a central chamber configured to hold silicon particles, the diameter of the central chamber being smaller than the diameter of the dehalogenation fluid-bed area; and
at least one inlet port configured for introducing a fluidizing gas into the central chamber.

26. The silicon deposition reaction of claim 25, wherein the diameter of the central chamber is from approximately ⅓ to ⅕ the diameter of the dehalogenation fluid-bed area.

27. The silicon deposition reaction of claim 25, wherein the fluidizing gas is selected from nitrogen, argon, helium or mixtures thereof.

28. The silicon deposition reaction of claim 25, wherein the flow of the fluidizing gas is sufficient to keep a fluidization state of the silicon particles inside the dehydrogenation fluid-bed area in the range of from approximately 0.8×Umf to 1.3×Umf, and wherein the temperature of the fluidizing gas introduced into the dehydrogenation fluid-bed area is at approximately the same or below the temperature of the fluidizing gas introduced into the dehalogenation fluid-bed area.

29. A method of producing high purity silicon, the method comprising:
injecting at least one silicon-bearing gas into a silicon deposition reactor, wherein the silicon deposition reactor comprises:
a gas injection zone comprising a gas distribution plate for injecting gas into the silicon deposition reactor, wherein the gas distribution plate is divided into a first chamber and a second chamber and wherein a gas in the first chamber will not mix with a gas in the second chamber before being injected into the silicon deposition reactor;
a bed of silicon particles disposed within the silicon deposition reactor; and
at least one heating system;
heating the silicon deposition reactor with the at least one heating system to a temperature sufficient for thermal decomposition of the silicon-bearing gas; and
collecting the high purity silicon that has been produced and deposited on the silicon particles.

30. The method of producing high purity silicon of claim 29, wherein the first chamber of the gas distribution plate comprises at least one orifice configured to allow a gas to pass from the first chamber into the silicon deposition reactor, and wherein a jet of gas exiting from the at least one orifice of the first chamber does not directly contact an internal surface of the silicon deposition reactor; and
wherein the second chamber of the gas distribution plate comprises at least one orifice configured to allow a gas to pass from the second chamber into the silicon deposition reactor and wherein a jet of gas exiting from the at least one orifice of the second chamber does not directly contact an internal surface of the silicon deposition reactor.

31. The method of producing high purity silicon of claim 30, wherein the first chamber of the gas distribution plate is configured to deliver at least one of a silicon-bearing gas, a fluidizing gas or a mixture thereof, and wherein the second chamber of the gas distribution plate is configured to deliver at least one of a silicon-bearing gas, a fluidizing gas or a mixture thereof.

32. The method of producing high purity silicon of claim 31, wherein the first chamber contains a fluidizing gas and the second chamber contains a silicon-bearing gas, and wherein the at least one orifice of the first chamber is configured so that the jets of the fluidizing gasses are injected in a bubbling phase before mixing with the silicon-bearing gas injected from the second chamber.

33. The method of producing high purity silicon of claim 29, the silicon deposition reactor further comprising:
a reaction chamber in fluid communication with the gas injection zone, wherein the reaction chamber is heated by the at least one heating system, and the gas injection zone is at a temperature less than the reaction chamber.

34. The method of producing high purity silicon of claim 33, wherein the first chamber of the gas distribution plate is configured to deliver a fluidizing gas and the second chamber of the gas distribution plate is configured to deliver a silicon-bearing gas and wherein the silicon-bearing gas and the fluidizing gas are configured to mix together before entering the reaction chamber.

35. The method of producing high purity silicon of claim 29, wherein the gas distribution plate is at a temperature below the thermal decomposition temperature of the silicon-bearing gas.

36. The method of producing high purity silicon of claim 33, further comprising an expansion zone positioned above the reaction chamber, wherein the expansion zone has a diameter greater than the reaction chamber.

37. The method of producing high purity silicon of claim 31, where the silicon-bearing gas configured to be delivered through the first chamber or the second chamber of the gas distribution plate is selected from: silane, disilane, trisilane, dichlorosilane, trichlorosilane, dibromosilane, tribromosilane, diodosilane, tribromosilane, silicon tetrachloride, silicon tetrabromide or mixtures thereof.

38. The method of producing high purity silicon of claim 31, where the fluidizing gas used in the first chamber or the second chamber is selected from: hydrogen, nitrogen, helium, argon, silicon tetrachloride, silicon tetrabromide, silicon tetraiodide, or mixtures thereof.

39. The silicon deposition reactor of claim 29, where the gas distribution plate is cooled by means of a thermal fluid.

40. The silicon deposition reactor of claim 31, where the gas configured to be delivered through one of the first chamber or the second chamber of the gas distribution plate is a fluidizing gas that excludes any silicon-bearing gas, and the fluidizing gas is preheated and configured to be introduced into the first chamber or the second chamber at a temperature between 550° C. and 650° C.

41. The method of producing high purity silicon of claim 33, wherein the reaction chamber is heated to a temperature of between approximately 500° C. to approximately 1200° C.

42. The method of producing high purity silicon of claim 33, wherein the reaction chamber is heated to a temperature ranging from approximately 700° C. to approximately 900° C.
